(19) United States
(12) Patent Application Publication
(10) Pub. No.: US 2026/0321560 A1
(43) Pub. Date: Oct. 15, 2026

(54) A METHOD FOR MANUFACTURING A CARBON-BASED RADIATION WINDOW AND A CARBON-BASED RADIATION WINDOW

(71) Applicant: AMETEK FINLAND OY, Espoo (FI)

(72) Inventors: Esa KOSTAMO, Helsinki (FI); Pekka TÖRMÄ, Helsinki (FI); Jari KOSTAMO, Espoo (FI); Tapio LANTELA, Espoo (FI)

(21) Appl. No.: 19/483,952

(22) PCT Filed: May 13, 2024
(86) PCT No.: PCT/FI2024/050228

§ 371 Date: Nov. 12, 2025

(30) Foreign Application Priority Data
May 15, 2023 (FI) 20235551

(51) Int. Cl. H01J 47/00; C23C 16/26

(52) U.S. Cl. CPC H01J 47/004; C23C 16/26

(57) ABSTRACT

A method is for manufacturing a radiation window for an X-ray measurement apparatus. The method includes depositing an amorphous carbon layer on a surface of a carrier. attaching A combined structure with he amorphous carbon layer and the carrier is attached to a region around an opening in a housing with the amorphous carbon layer facing the housing. At least part of the carrier is detached. A radiation window is for an X-ray measurement apparatus.

### CROSS-REFERENCE TO RELATED APPLICATIONS

This application is a National Stage Application of PCT/FI2024/050228, filed May 13, 2024, which claims benefit of priority to FI Patent Application No. 20235551 filed on May 15, 2023, and which applications are incorporated herein by reference. To the extent appropriate, a claim of priority is made to each of the above disclosed applications.

### TECHNICAL FIELD

The invention concerns in general the technical field of radiation windows. Especially the invention concerns radiation windows for X-ray measurement apparatuses.

### BACKGROUND

A radiation window is a part of a measurement apparatus that allows a desired part of electromagnetic radiation, e.g. X-ray radiation, to pass through. In many cases the radiation window must nevertheless be gastight, in order to seal and protect an enclosure where reduced pressure and/or a particular gas contents prevail. In order to cause as little absorption as possible of the desired radiation, a major part of the radiation window should consist of a thin foil made from materials preferably comprising only elements with small atomic number. The radiation window foil may be attached to a housing of the radiation window by a selected joining method.

Beryllium is known as a good material for radiation window foils especially in X-ray measurement apparats, because it has a low atomic number (4) and consequently exhibits very low absorption of X-rays. Another characteristic of beryllium that makes it very useful for radiation window foils is its exceptional flexural rigidity. The thinnest beryllium foils that are commercially available for use in radiation windows at the time of writing this description have a thickness in the order of 8 micrometres. At the time of writing this description it appears that the manufacturing of the beryllium foil from an ingot by rolling has met its limits in the sense that it has not been shown capable of manufacturing beryllium foils thinner than 8 micrometres so that they would still be sufficiently gastight. This phenomenon is associated with the relatively large grain size (larger than foil thickness). Grain boundaries in the beryllium foil tend to cause gas leaks through the foil. Additionally, beryllium has disadvantages as a material because it is toxic. This brings additional requirements for the manufacturing process. Also, the utilization of beryllium is uncer-tain due to tightening requirements by different national authorities.

One optional material for manufacturing radiation window foils especially in X-ray measurement apparatuses is boron carbide. The boron carbide is not toxic, and it is environmentally sustainable also in the long term. If the boron carbide layer is thin e.g. less than 0.5 micrometres, its mechanical strength would be too low causing that the layer becomes fragile. However, if the thickness of the boron carbide layer is increased, e.g. more than 2 micrometres, the crystal size inside the boron carbide layer starts to increase causing that the layer becomes fragile. Thus, the mechanical strength of the boron carbide cannot be increased by increasing the thickness of the boron carbide layer. Typically, the radiation window foil made of boron carbide further needs one or more radiation filtering layers to block out unwanted wavelengths of electromagnetic radiation, such as ultraviolet (UV) radiation, visible light (VIS), and/or infrared (IR) radiation, etc .. The one or more radiation filtering layers are typically made of aluminium. However, aluminium has al-ready a higher atomic number (13) compared to beryllium (4) and boron (5). Thus, radiation filtering layer(s), i.e. radiation blocking layer(s), or other layers made of aluminium compromise the bandpass performance for X-rays especially in the applications where efficient light filtering, i.e. blocking, e.g. against daylight, is required. Another disadvantage of aluminium is related to its temperature tolerance. Building an X-ray measurement apparatus typically includes a vacuum sealing process, which is done at elevated temperatures above 150 °C for removing moisture and other possible outgassing sources. Even though sealing temperature is well below the melting point of aluminium it is high enough to cause clustering and pin hole formation on the thin film layer made of aluminium. Clustered pin hole containing aluminium has decreased blocking efficiency causing performance and yield losses.

Yet another optional material for manufacturing radiation window foils especially in X-ray measurement apparatuses is graphene. However, a monolayer graphene does not provide enough mechanical strength. To improve the mechanical strength of the radiation window foil a multilayer graphene construction, i.e. structure, may be used. The multilayer graphene construction typically comprises tens or hundreds or even thousands graphene monolayers stacked layer-by-layer one on another. Preferably, the multilayer graphene construction comprises at least 350 graphene monolayers. However, stacking graphene monolayers layer by layer becomes impractical. Stacking few tens or hundreds graphene monolayers layer-by-layer may be possible, but with a multilayer graphene construction comprising few tens or hundreds graphene monolayers it is only possible to achieve a limited thickness, as the ideal single layer graphene thickness is 0.345 nanometres. This limits, for example, the manufacturing of radiation windows with a large surface area, which need thicker window foils, because the larger radiation windows are subjected to a greater stress than smaller radiation windows. Moreover, a high-quality multilayer graphene construction cannot be grown directly on a silicon wafer. To be able to grow high quality multilayer graphene construction on the silicon wafer a catalyst is needed. However, the multilayer graphene construction grown on catalyst exhibits nonuniformity that weakens the window foil.

Thus, there is a need to mitigate the aforementioned problems and develop a solution for providing thin and gastight radiation windows.

### SUMMARY

The following presents a simplified summary in order to provide basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

An objective of the invention is to present a radiation window and a method for manufacturing a radiation window for an X-ray measurement apparatus. Another objective of the invention is that the radiation window and the method for manufacturing a radiation window for an X-ray measurement apparatus enable providing a radiation window with a radiation window foil that is thin, absorbs very little X-rays, and absorbs unwanted wavelengths of electromagnetic radiation including ultraviolet (UV) radiation, visible light (VIS), and infrared (IR) radiation without aluminium layer.

The objectives of the invention are reached by a method and a radiation.

According to a first aspect, a method for manufacturing a radiation window for an X-ray measurement apparatus is provided, wherein the method comprises: depositing an amorphous carbon layer on a surface of a carrier; attaching a combined structure comprising the amorphous carbon layer and the carrier to a region around an opening in a housing with the amorphous carbon layer facing said housing, and detaching at least part of the carrier.

The amorphous carbon layer may be pyrolytically deposited on the surface of the carrier.

The detaching the at least part of the carrier may comprise detaching the middle area of the carrier to form an additional support structure.

The carrier may be a silicon wafer.

The thickness of the amorphous carbon layer may be between 0.5 and 3 micrometres.

According to a second aspect, a radiation window for an X-ray measurement apparatus is provided, wherein the radiation window comprises: a housing that defines an opening; and a radiation window foil comprising an amorphous carbon layer attached to the housing at a region around the opening to cover the opening of the housing.

The amorphous carbon layer may be provided by a pyrolytic deposition technique.

The radiation window foil may further comprise an additional support structure on an opposite side of the amorphous carbon layer than the housing.

The additional support structure may be made of silicon.

The thickness of the amorphous carbon layer may be between 0.5 and 3 micrometres.

Various exemplifying and non-limiting embodiments of the invention both as to constructions and to methods of operation, together with additional objects and advantages thereof, will be best understood from the following description of specific exemplifying and non-limiting embodiments when read in connection with the accompanying drawings.

The verbs “to comprise” and “to include” are used in this document as open limitations that neither exclude nor require the existence of unrecited features. The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF FIGURES

The embodiments of the invention are illustrated by way of example, and not by way of limitation, in the figures of the accompanying drawings.

FIG. 1 illustrates schematically an example of a method for manufacturing a radiation window and a radiation window.

FIG. 2 illustrates schematically a non-limiting example of a radiation window further comprising one or more additional layers and/or structures.

### DETAILED DESCRIPTION OF THE INVENTION

In this description we use the following vocabulary. A layer means a quantity of essentially homogeneous material that by its form has much larger dimensions in two mutually orthogonal directions than in the third orthogonal direction. In most cases of interest to the present invention, the dimension of a layer in said third orthogonal direction (also referred to as the thickness of the layer) should be constant, meaning that the layer has uniform thickness. A foil is a structure, the form of which may be characterised in the same way as that of a layer (i.e. much larger dimensions in two mutually orthogonal directions than in the third orthogonal direction) but which may comprise one or more layers. When the foil comprises two or more layers, said two or more layers are placed and/or attached together. A radiation window foil 107 is a foil that has suitable characteristics (low absorption of desired radiation, sufficient gastightness, sufficient mechanical strength etc.) for use in a radiation window 100 of a measurement apparatus, e.g. an X-ray measurement apparatus. A radiation window 100 is an entity that comprises a piece of a radiation window foil 107 attached to an annular housing (i.e. a support structure) 105 so that electro-magnetic radiation may pass through an opening 104 defined by the housing 105 without having to penetrate anything else than said piece of radiation window foil 107.

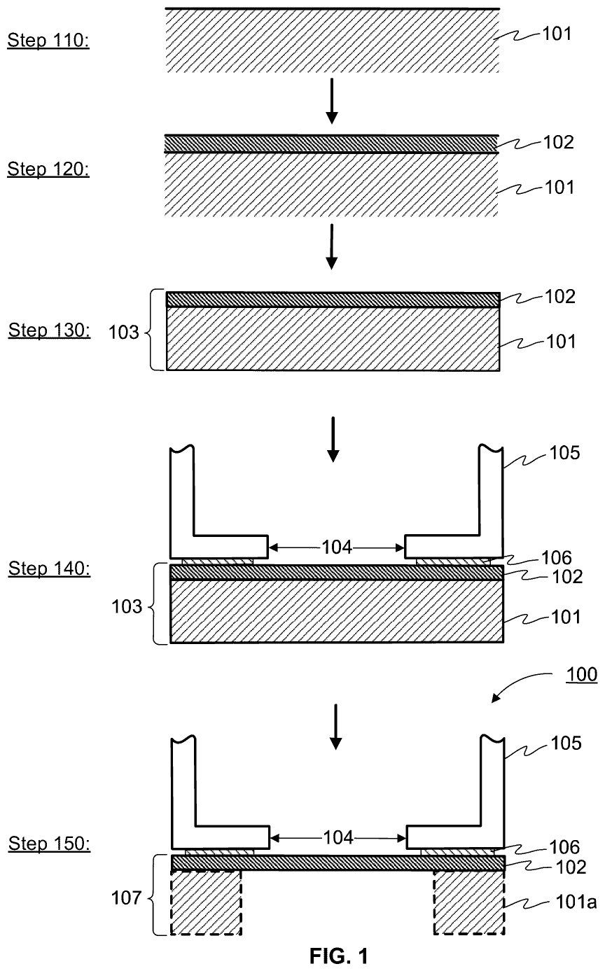

FIG. 1 illustrates an example of a workpiece in various steps of an example method for manufacturing a radiation window 100 for an X-ray measurement apparatus. FIG. 1 illustrates a cross-sectional view of the workpiece in the various steps of the example method. The X-ray measurement apparatus may for example be, but is not limited to, an X-ray fluorescence (XRF) spectrometer or a radiation detector. The topmost step 110 of the example method of FIG. 1 illustrates a carrier 101. At least one surface of the carrier 101 may be polished. In FIG. 1, the polished surface faces up-wards. The carrier 101 may be a silicon wafer. As an example, silicon wafers are routinely polished to achieve rms (root mean square) roughness values in the order of fractions of a nanometre, which is a sufficient for the purposes of the present invention. In addition or as alternative to silicon, the carrier 101 may be manufactured from some other solid material that can be polished to the required level of smoothness and that is preferably etchable with some reasonably common and easily handled etching agent. According to a non-limiting example, the thickness of the carrier 101 may be approximately 725 micrometres.

In the next step 120 of the example method of FIG. 1 an amorphous carbon layer 102 is produced on a surface of the carrier 101. Preferably, the amorphous carbon layer 102 is produced on the polished surface of the carrier 101. The amorphous carbon layer 102 is produced on the surface of the carrier 101 by depositing. For example, the amorphous carbon layer 102 may be pyrolytically deposited on the surface of the carrier 101, i.e. a pyrolytic deposition technique may be used to produce the amorphous carbon layer 102 on the surface of the carrier 101. In other words, the material of the amorphous carbon layer 102 is pyrolytically deposited carbon which is primarily or fully composed of amorphous carbon. The thickness of the amorphous carbon layer 102 may for example be between 0.5 and 3 micrometres. The amorphous carbon is a carbonaceous material that has no crystalline structure. The amorphous carbon is a low atomic number (6) alloy providing the strength on the radiation window structure 100. The low atomic number of the amorphous carbon also enables that the amorphous carbon layer 102 exhibits very low absorption of X-rays, i.e. allows a desired part of electromagnetic radiation, e.g. X-ray radiation, to pass through, especially at the energy range that is important in energy dispersive analysis of elements, e.g. in the X-ray fluorescence analysis. The amorphous carbon minimizes crack propagation better than materials with crystalline structure, e.g. graphene. The amorphous carbon layer 102 serves also as an etch stop layer. This means that a separate etch stop layer is not needed in the radiation window 100, but may optionally by applied. The objective of the etch stop layer is to stop an etching agent, which in a latter method step 150 may be used to remove at least part of the carrier 101 as will be described later in this application. In other words, the amorphous carbon layer 102 is impervious for the etching agent. If one or more additional layers are produced on top of the amorphous carbon layer 102, the amorphous carbon layer 102 as the etch stop layer keeps the etching agent from affecting the one or more additional layers that may come on top of the amorphous carbon layer 102. The amorphous carbon layer 102 serves also as a radiation filtering layer for blocking out unwanted wavelengths of electromagnetic radiation, such as ultraviolet (UV) radiation, visible light (VIS), and/or infrared (IR) radiation, etc .. This means that a separate radiation filtering layer(s) made e.g. from aluminium is not needed in radiation window 100, but may optionally be applied. The separate radiation filtering layers are typically made of aluminium. Thus, the use of the amorphous carbon layer 102 reduces the need for the use of aluminium. The amorphous carbon layer 102 provides a gastight radiation window. This means that a separate layer, e.g. the separate etch stop layer, is not needed for providing the gastight radiation window. It is well-known that each carbonaceous material, such as amorphous carbon, graphene, multilayer graphene, and highly oriented pyrolytic graphite (HOPG), etc., has a specific Raman spectrum. Thus, different carbonaceous materials may be discerned from each other based on the Raman spectra of the carbonaceous materials. In other words, Raman spectroscopy may be used to verify whether the carbonaceous material of the radiation window 100 is amorphous carbon or some other carbonaceous material.

In the next step 130 of the example method of FIG. 1 a combined structure 103 comprising the carrier 101 and the amorphous carbon layer 102 is cut into pieces, so that a single piece (e.g. a single chip) is suitably sized for use in one radiation window 100. As an example, the carrier 101 might have originally been a silicon wafer with a diameter of several inches, while the diameter of a piece sufficient for a radiation window 100 may for example be between 1 and 2 centimetres. On the other hand, the present invention does not limit the maximum size of a radiation window 100 to be made. As another example, a radiation window 100 according to an example might have 10 millimetres as the diameter of the foil-covered opening 104 for the radiation to pass through. Cutting the combined structure 103 into pieces at this step of the method is not an essential requirement of the manufacturing method, but it is advantageous in the sense that a larger number of completed radiation windows 100 can be very practically manufactured from a single original workpiece.

In the next step 140 of the example method of FIG. 1 the piece of the combined structure 103 comprising the carrier 101 and the amorphous carbon layer 102 is attached (i.e. joined) to an annular region around the opening 104 in the housing 105 (i.e. the support structure) with the amorphous carbon layer 102 facing the housing 105. In other words, the combined structure 103 is attached to the region around the opening 104 in the housing 105 to cover the opening 104 of the housing 105 so that the housing 105 is in the opposite side of the amorphous carbon layer 102 than the carrier 101. The material of the housing 105 may be for example, but is not limited to, Kovar, nickel, zirconium, or stainless steel. A variety of joining methods may be used for the attachment of the combined structure 103 to the housing 105. For example, soldering or gluing may be used for the attachment of the combined structure 103 to the housing 105, but the invention is not limited to these, and any other joining methods may be used as well. The solder material used in the soldering may for example be indium. The adhesive material used in the gluing may for example be epoxy adhesive. The cross-section of an exaggeratedly thick layer of glue or solder 106 is schematically shown in FIG. 1. The illustration of the glue or solder 106 is only schematic in FIG. 1, and it does not mean that a flat layer of glue or solder on the planar surface between the housing 105 and the amorphous carbon layer 102 would be the only possible alternative. The fact that the carrier 101 is still present at the step of attaching the combined structure to the housing 105 enables that the handling is easy and there is no need to worry about wrinkling or other kinds of deformation of the radiation window foil 107 at this stage.

The descriptor “annular” should be understood in a wide sense. The invention does not require the annular housing 105 (or other annular structures) to have e.g. a circular form. For example, it is sufficient that the housing structure 105 offers some edges and/or region around the opening 104, to which the radiation window foil 107 may be attached tightly and extensively enough to keep the radiation window foil 107 in the completed structure securely in place, and in those applications where gastightness is required-to form a gastight seal.

In the last step 150 illustrated in the example of FIG. 1 at least part of the carrier 101 is detached. If the carrier 101 is completely detached, the radiation window foil 107 comprising the amorphous carbon layer 102 is left to cover the opening 104 of the housing 105. Alternatively, if the carrier 101 is partly detached the radiation window foil 107 covering the opening of the housing 105 may further comprise an additional support structure 101a formed by the remaining part of the carrier 101. For example, the middle area of the carrier 101 may be detached to form an annular additional support structure 101a. The annular additional support structure 101a does not disturb the desired part of electromagnetic radiation to pass through the radiation window 100 or cause more unwanted absorption or spurious responses, because the annular additional support structure 101a does not extend to the middle of the radiation window 100, wherein the opening 104 in the housing 105 resides. The annular additional support structure 101a is illustrated in FIG. 1 with the dashed lines to indicate that the carrier 101 may be detached either partly or completely. The detaching of the at least part of the carrier 101 may for example comprise etching away the at least part of the carrier 101. Alternatively, other methods may be used for detaching the at least part of the carrier 101. Etching is considered to be the most advantageous way of carefully removing the carrier 101 while leaving the other layers intact. As an example, if the carrier 101 is made of silicon, potassium hydroxide (KOH) is one suitable etching agent.

After the above-described method steps, post-processing steps such as rinsing, drying, and testing may be applied according to need. The manufactured radiation window 100 may be attached to the X-ray measurement apparatus.

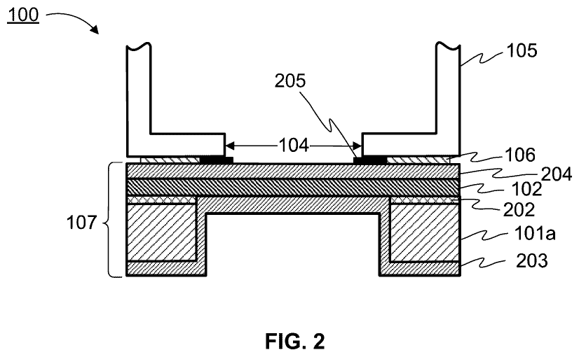

According to an example, the radiation window foil 107 of the radiation window 100 may further comprise one or more additional layers and/or structures 202, 203, 204, 205. For example, a separate etch stop layer 202 may be produced between the carrier 101 and the amorphous carbon layer 102. In other words, an additional method step to produce, e.g. deposit, the separate etch stop layer 202 may be performed between the method steps 110 and 120, wherein the etch stop layer 202 is produced on the polished surface of the carrier 101 and the amorphous carbon layer 102 may then be produced on the opposite side of the etch stop layer 202 than the carrier 101. The etch stop layer 202 stretches across the whole polished surface of the carrier 101, i.e. the etch stop layer 202 is between the polished surface of the carrier 101 and the amorphous carbon layer 202 throughout. The material of the etch stop layer 202 should be applicable for deposition in thin layers (for example in the order of 5 to 200 nanometres), and it should neither significantly absorb radiation nor produce any awkwardly handled anomalities at the wavelengths of electromagnetic radiation at which the radiation window 100 is to be used. For example, if the carrier 101 is made of silicon, one advantageous material for the etch stop layer 202 is silicon nitride. Alternatively, other advantageous materials for the etch stop layer 202 may for example be, but are not limited to, aluminium oxide and silicon dioxide. Suitable methods for depositing the etch stop layer 202 include, but are not limited to, chemical vapour deposition, pulsed laser deposition, and atomic layer deposition. According to an example, the etch stop layer 202 may be left on the amorphous carbon layer 102, after the removal of the carrier 101 at least partly at the step 150. In that case, the etch stop layer 202 needs to be very thin and absorb very little X-rays. For example, the material of the etch stop layer 202 left on the amorphous carbon layer 102 may be silicon nitride. When the etch stop layer 202 is left on the amorphous carbon layer 102, the etch stop layer 202 may also act as a gastight barrier layer. Alternatively, the etch stop layer 202 may be removed at least partly after the removal of the carrier 101 at least partly at the step 150. In case, the carrier 101 is removed partly, e.g. the middle part of the carrier 101 is removed, preferably a respective part of the etch stop layer 202, i.e. the respective middle part of the etch stop layer 202, may be removed. When the etch stop layer 202 is removed at least from the area of the opening 104, the etch stop layer 202 does not disturb the desired part of electromagnetic radiation to pass through the radiation window 100 or cause more unwanted absorption or spurious responses. For example, the material of the etch stop layer 202 removed at least partly may be aluminium oxide or silicon dioxide. The at least partial removal of the etch stop layer 202 may be performed by using some other etching method than the etching method used to remove the carrier at least partly at the step 150. Alternatively or in addition, one or more additional layers 203 may be produced on the exposed amorphous carbon layer 102 after detaching the at least part of the carrier 101 at the step 150. For example, the radiation window foil 107 may further comprise a first radiation filtering layer as the additional layer 203. Alternatively or in addition, at least one second radiation filtering layer and/or other layer(s) 204 may also be produced on that side of the amorphous carbon layer 102 that will face the housing 105, before making the attachment at the step 140. The at least one radiation filtering layer 203, 204 may for example be, but is not limited to, made of zirconium, niobium, or silver. The at least one radiation filtering layer 203, 204 may also be made of aluminium, but as discussed above the use of aluminium has known drawbacks. Thus, the aluminium is not preferred material for the at least one radiation filtering layer 203, 204, i.e. the first and second radiation filtering layers. According to a non-limiting example, the thickness of the at least one thin film layer 203, 204 may for example be between 10 to 300 nanometres. Alternatively or in addition, the radiation window 100 may comprise an annular edge strengthening structure 205 between the amorphous carbon layer 102 and the housing 105 (or between the second radiation filtering layer 204 and the housing 105 in case the radiation window foil 107 comprises further the second radiation filtering layer 204). The edge strengthening structure 205 may preferably overlap with the opening 104, when the radiation window foil 107 is attached to the housing 105. The edge strengthening structure 205 improves the strength of the radiation window foil 107 attached to the housing 105 by distributing a possible point stress on the radiation window foil 107 caused for example by a sharp object on the housing 105 or any other non-idealities to a wider area on the radiation window foil 107 pre-venting or at least reducing the breakage of the radiation window foil 107. FIG. 2 illustrates schematically a non-limiting example of the radiation window 100 further comprising the one or more additional layers and/or structures. In the example of FIG. 2. the radiation window 100 comprises the etch stop layer 202, the first radiation filtering layer 203, the second radiation filtering layer 204, and the edge strengthening structure 205, but the radiation window 100 may also comprise only one or more of these additional layers and structures. In the example of FIG. 2, the etch stop layer 202 is removed partly after the partial removal of the carrier 101, i.e. the middle part of the etch stop layer 101 respective to the removed middle part of the carrier 101.

Advantages of the present invention described above include the possibility of manufacturing radiation windows for X-ray measurement apparatuses, where the radiation window foil 107 is very thin and yet gastight, absorbs very little X-rays, absorbs unwanted wavelengths of electromagnetic radiation also without aluminium layer, and has good strength.

The illustrated dimensions in the drawings are not to scale and not comparable to each other; they have been selected only for graphical clarity in the drawings.

The specific examples provided in the description given above should not be construed as limiting the applicability and/or the interpretation of the appended claims. Lists and groups of examples provided in the description given above are not exhaustive unless otherwise explicitly stated.

1. A method for manufacturing a radiation window for an X-ray measurement apparatus, the method comprises:
depositing an amorphous carbon layer on a surface of a carrier;
attaching a combined structure comprising the amorphous carbon layer and the carrier to a region around an opening in a housing with the amorphous carbon layer facing said housing and
detaching at least part of the carrier.

2. The method according to claim 1, wherein the amorphous carbon layer is pyrolytically deposited on the surface of the carrier.

3. The method according to claim 1, wherein the detaching the at least part of the carrier comprises detaching a middle area of the carrier to form an additional support structure.

4. The method according to claim 1, wherein the carrier is a silicon wafer.

5. The method according to claim 1, wherein a thickness of the amorphous carbon layer is between 0.5 and 3 micrometres.

6. A radiation window for an X-ray measurement apparatus, the radiation window comprises:
a housing that defines an opening; and
a radiation window foil comprising an amorphous carbon layer attached to the housing at a region around the opening to cover the opening of the housing.

7. The radiation window according to claim 6, wherein the amorphous carbon layer comprises a pyrolytic deposited layer.

8. The radiation window according to claim wherein the radiation window foil further comprises an additional support structure on an opposite side of the amorphous carbon layer than the housing

9. The radiation window according to claim 8, wherein the additional support structure is made of silicon.

10. The radiation window according to claim 6, wherein a thickness of the amorphous carbon layer is between 0.5 and 3 micrometres.
